(19) United States
(12) Patent Application Publication
(10) Pub. No.: US 2024/0405513 A1
(43) Pub. Date: Dec. 5, 2024

(54) NANOWIRE LASER AND MANUFACTURING METHOD THEREFOR

(71) Applicant: Nippon Telegraph and Telephone Corporation, Tokyo (JP)

(72) Inventors: Masato Takiguchi, Tokyo (JP); Masaya Notomi, Tokyo (JP); Satoshi Sasaki, Tokyo (JP); Guoqiang Zhang, Tokyo (JP); Kota Tateno, Tokyo (JP); Hisashi Sumikura, Tokyo (JP); Akihiko Shinya, Tokyo (JP)

(21) Appl. No.: 18/689,025

(22) PCT Filed: Oct. 8, 2021
(86) PCT No.: PCT/JP2021/037314

§ 371 Date: Mar. 4, 2024

(51) Int. Cl. H01S 5/11

(52) U.S. Cl. CPC H01S 5/11

(57) ABSTRACT

A nanowire laser includes a nanowire on a substrate and a one-dimensional photonic crystals on ends the nanowire. The nanowire is disposed on a substrate. The nanowire has an elliptical cross-sectional shape with a longitudinal direction parallel to a plane of the substrate. The one-dimensional photonic crystals are separated from each other to form a resonator.

### CROSS-REFERENCE TO RELATED APPLICATIONS

This application is a national phase entry of PCT Application No. PCT/JP2021/037314, filed on Oct. 8, 2021, which application is hereby incorporated herein by reference.

### TECHNICAL FIELD

The embodiments of the present invention relates to a nanowire laser and a method of producing the same.

### BACKGROUND

In recent years, research on optical elements using semiconductor nanowires has been actively conducted. A nanowire is composed of a semiconductor and is a very small structure with a diameter of several tens of nm to several μm and a length of several μm. Nanowires can be grown from a substrate in bulk all at once and can also be grown directly on silicon substrates under certain conditions. For this reason, nanowires are considered to be important nano-materials which can be used not only in future semiconductor devices but also in quantum information devices and optoelectronic devices (NPL 1).

Until now, although nanowires have been studied with regard to electronic devices such as transistors and sensing applications, by changing the composition of the semiconductors which make up nanowires, it is possible to emit light in various wavelength bands, they are considered promising with regard to a laser.

Nanowire-based lasers have been demonstrated in various wavelength bands. Particularly, since communication wavelength band nanowire lasers with respect to which silicon is transparent can be integrated and operated in silicon optical circuits, communication wavelength band nanowire lasers are promising candidates as a light source which could be used for optoelectronic chips in the future. With regard to this, there is a demand for the realization of a nanowire laser which selectively oscillates TE polarized waves which can be efficiently coupled to an optical waveguide when integrated into a silicon optical circuit and used as a device.

### CITATION LIST

### Non Patent Literature

NPL 1 M. Notomi et al., “Nanowire photonics toward wide wavelength range and subwavelength confinement [Invited]”, Optical Materials Express, vol. 10, No. 10, pp. 2560 to 2596, 2020.
NPL 2 M. Takiguchi et al., “Thermal effect of InP/InAs nanowire lasers integrated on different optical platforms”, OSA Continuum, vol. 4, No. 6, pp. 1838 to 1845, 2021.

### SUMMARY

### Technical Problem

However, the nanowire lasers in the related art operate in multiple modes in which oscillation is performed in both TE and TM and have the problem that they cannot be efficiently coupled to optical waveguides.

The present invention was made to solve the above problems, and an object of the present invention is to provide a nanowire laser capable of selectively oscillating a TE polarized wave and efficiently coupling it to an optical waveguide.

### Solution to Problem

A nanowire laser according to embodiments of the present invention includes: a nanowire formed on a substrate and having an elliptical cross-sectional shape whose longitudinal direction is parallel to a plane of the substrate; and a resonator.

Also, a method of producing a nanowire laser according to embodiments of the present invention includes: a disposition step of disposing a nanowire with a circular cross section on a substrate; a processing step of etching the nanowire from information perpendicular to a plane of the substrate using a dry etching method having perpendicular anisotropy and making a shape of a cross section of the nanowire have an elliptical shape whose longitudinal direction is parallel to the plane of the substrate; and a resonator step of forming a resonator.

### Advantageous Effects of Embodiments of the Invention

As described above, according to embodiments of the present invention, since a nanowire having an elliptical cross-sectional shape is used, it is possible to provide a nanowire laser capable of selectively oscillating a TE polarized wave and efficiently coupling it to an optical waveguide.

### BRIEF DESCRIPTION OF THE DRAWINGS

FIG. 1 is a perspective view showing a configuration of a nanowire laser according to Embodiment 1 of the present invention.

FIG. 2A is a perspective view showing a state of the nanowire laser in an intermediate step for explaining a method of producing a nanowire laser according to Embodiment 1 of the present invention.

FIG. 2B is a perspective view showing a state of the nanowire laser in the intermediate step for explaining the method of producing a nanowire laser according to Embodiment 1 of the present invention.

FIG. 2C is a perspective view showing a state of the nanowire laser in the intermediate step for explaining the method of producing a nanowire laser according to Embodiment 1 of the present invention.

FIG. 3 is a distribution diagram showing an electromagnetic field simulation of a photonic crystal structure using one-dimensional photonic crystals 103a and 103b of the nanowire laser according to Embodiment 1.

FIG. 4A is a photograph showing an electron microscope image of the nanowire laser according to Embodiment 1 which has been actually prepared.

FIG. 4B is a photograph showing an electron microscope image of an actually prepared nanowire laser according to Embodiment 1.

FIG. 5A is a characteristic diagram showing a change in effective refractive index (equivalent refractive index) with respect to a change in diameter of a nanowire with a circular cross section.

FIG. 5B is a characteristic diagram showing a change in effective refractive index (equivalent refractive index) with respect to a change in short diameter of nanowires having an elliptical cross section.

FIG. 6 is a characteristic diagram showing a change in emission intensity of a nanowire laser before and after dry etching treatment to remove a damaged portion and to form an ellipse.

FIG. 7 is a perspective view showing a configuration of a nanowire laser according to Embodiment 2 of the present invention.

FIG. 8A is a perspective view showing a state of a nanowire laser in an intermediate step for explaining a method of producing a nanowire laser according to Embodiment 2 of the present invention.

FIG. 8B is a perspective view showing a state of a nanowire laser in an intermediate step for explaining the method of manufacturing the nanowire laser according to Embodiment 2 of the present invention.

FIG. 9 is a characteristic diagram showing optical confinement in a fundamental mode of a nanowire laser in which a nanowire is disposed on a metal substrate.

### DETAILED DESCRIPTION OF ILLUSTRATIVE EMBODIMENTS

A nanowire laser according to an embodiment of the present invention will be described below.

### Embodiment 1

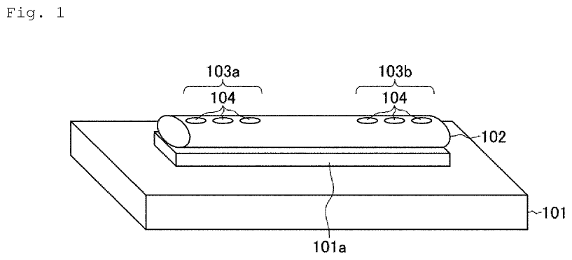

First, a nanowire laser according to Embodiment 1 of the present invention will be described with reference to FIG. 1. The nanowire laser is composed of a nanowire 102 formed on a substrate 101 and one-dimensional photonic crystals 103a and 103b formed on one end side and the other end side of the nanowire 102, respectively.

In this example, a convex portion 101a having a flat upper surface is formed on a substrate 101 and a nanowire 102 is disposed on the convex portion 101a. The upper surface of the convex portion 101a is formed parallel to the plane of the substrate 101. In addition, the convex portion 101a has substantially the same area as the nanowire 102 when viewed from above. The nanowire 102 has an elliptical cross-sectional shape whose longitudinal direction is parallel to the plane of the convex portion 101a (substrate 101). Also, the nanowire 102 has a thickness in which the degeneracy of the fundamental mode allowed to be resolved is allowed.

One-dimensional photonic crystals 103a and 103b are composed of grating elements 104 which are linearly and periodically provided at predetermined intervals. The grating element 104 is the portion of the index of refraction with respect to the nanowire 102 and is a columnar (for example, cylindrical) hole. The one-dimensional photonic crystal 103a and the one-dimensional photonic crystal 103b configured in this manner are separated from each other to form a resonator.

According to this nanowire laser, laser oscillation can be obtained by irradiating the nanowire 102 with excitation light. In addition, laser oscillation can be caused by injecting carriers through current injection instead of optical excitation. In this case, an active layer, a p-type region, and an n-type region are formed in the nanowire 102 with the active layer disposed therebetween. Laser oscillation can be caused by injecting current into the p-type region and the n-type region.

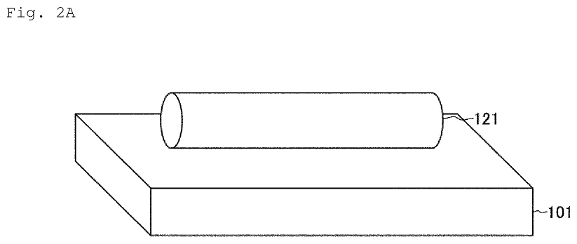

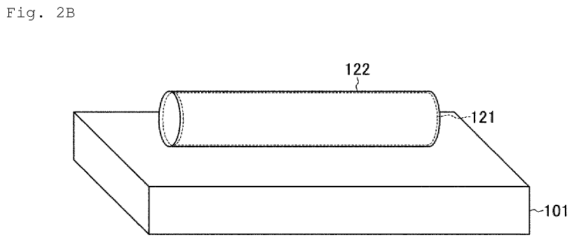

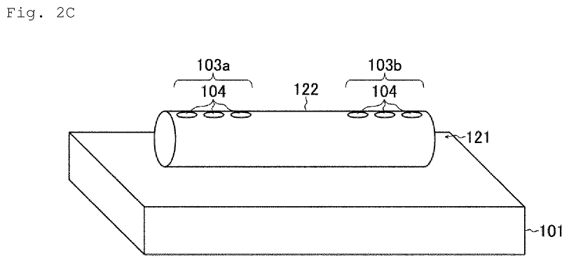

A method of producing a nanowire laser according to Embodiment 1 will be described below with reference to FIGS. 2A, 2B, and 2C.

First, as shown in FIG. 2A, a nanowire 121 having a circular cross section and a predetermined diameter are prepared and the prepared nanowire 121 is disposed (transferred) on a substrate 101 (disposition step). Subsequently, an oxide film 122 is formed on a surface of the nanowires 121, as shown in FIG. 1B. For example, the oxide film 122 can be formed while the nanowire 121 is coated with the oxide film 122 using a well-known atomic layer deposition (ALD) device. In addition, since the adhesion between the substrate 101 and the nanowires 121 is improved by forming the oxide film 122 in this way, it can be expected that, finally, the nanowires will be prevented from blowing off when the substrate 101 is washed in a later process.

Subsequently, as shown in FIG. 2C, a one-dimensional photonic crystal 103a and a one-dimensional photonic crystal 103b are formed on each of the one end side and the other end side of the nanowire 121 with a space therebetween to form a resonator (resonator process). For example, openings are formed in the oxide film 122 in which the grating elements 104 are to be formed through electron beam lithography. Subsequently, the nanowires 121 are etched through a dry etching method using the oxide film 122 with the openings as a mask to form the grating elements 104, thereby forming the one-dimensional photonic crystals 103a and the one-dimensional photonic crystals 103b.

Also, the grating elements 104 can be formed by processing using a focused ion beam (FIB). According to FIB processing, the degree of difficulty of preparation can be lowered as compared with the above-described method. Here, in the FIB processing, a thickness of the oxide film 122 is desirably about 100 nm at most to prevent the occurrence of charge-up during observation.

Subsequently, the nanowires 121 are etched from above perpendicularly to the plane of the substrate 101 through a dry etching method having perpendicular anisotropy and an elliptical nanowire 102 having a cross-sectional shape whose longitudinal direction is parallel to the plane of the substrate 101 is formed (processing step). This processing changes the aspect ratio of the diameter of the nanowires 121 to form the nanowires 102 with an elliptical cross section. Furthermore, through this processing, the substrate 101 around the nanowires 102 is also etched to form the convex portions 101a and the nanowires 102 are disposed on the convex portions 101a (refer to FIG. 1).

Although the FIB processing described above has extremely high processing accuracy and can form any structure, the ions (such as Ga and Ne ions) used for processing may damage the nanowires 121, and the ions which are shot may act as absorbing media, resulting in significant deterioration of the light emission characteristics. On the other hand, it is possible to make the cross section elliptical and remove the damage received in the FIB processing by performing dry etching with perpendicular anisotropy for changing the aspect ratio of the diameter as described above.

According to the above-described Embodiment 1, the nanowire 102 has an elliptical cross-sectional shape with a different direction so that mode selectivity is improved and TE polarized waves can be selectively oscillated. Furthermore, it is possible to selectively oscillate the TE polarized wave in a single mode by making the nanowire 102 thick enough to eliminate the degeneracy of the fundamental mode.

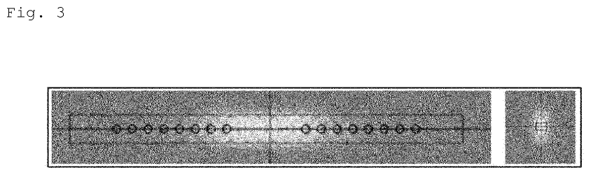

Furthermore, according to the resonator using the one-dimensional photonic crystals 103a and 103b, a higher reflectance can be obtained and an oscillation threshold value can be lowered as compared with a Fabry-Perot resonator using end face reflection of nanowires. As shown in the electromagnetic field simulation shown in FIG. 3, this photonic crystal structure makes it possible to form a resonator in the nanowire 102 with an elliptical cross section and strongly confine light. Although the edge reflection is usually about 30%, it is possible to increase the reflectance to 90% or more by using a photonic crystal structure. Note that the reflectance of the photonic crystal structure can be controlled by increasing the number of grating elements or finely adjusting the diameter of each grating element.

As described above, according to Embodiment 1 in which the resonator has a high reflectance, a threshold value of the laser oscillation can be lowered and continuous oscillation can be realized at room temperature. Until now, nanowire lasers have not achieved continuous oscillation at room temperature, which is due to their high lasing threshold value. It is believed that, when the threshold value of the laser oscillation is high, there is gain saturation and gain broadening due to heat effects, and continuous oscillation is not possible, resulting in pulsed oscillation (NPL 2). On the other hand, since a high reflectance is obtained in the resonator in Embodiment 1, the threshold value of the laser oscillation can be lowered, and as a result, continuous oscillation at room temperature is possible.

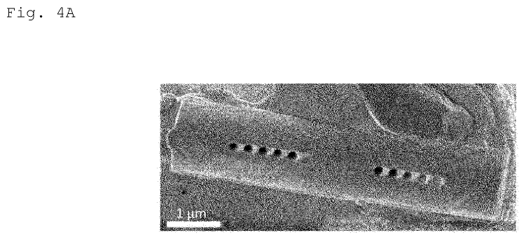

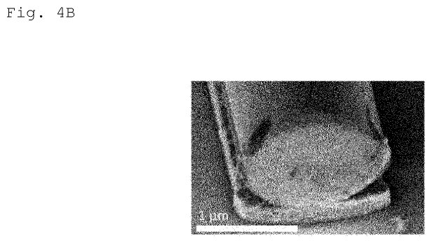

An electron microscope image of a nanowire laser actually prepared using FIB is shown in FIG. 4A. Periodic air holes are prepared in the nanowire. Furthermore, FIG. 4B shows an electron microscope image of the nanowire observed from an oblique direction of 45 degrees after the surface layer has been scraped off by dry etching in the direction perpendicular to the substrate surface. The cross section of the nanowires is elliptical, demonstrating that the structures of the present invention can be prepared.

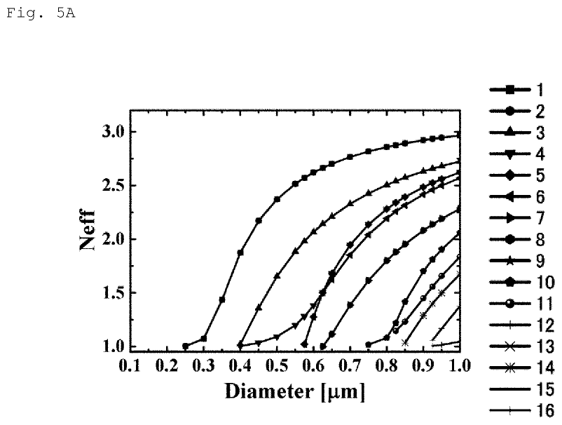

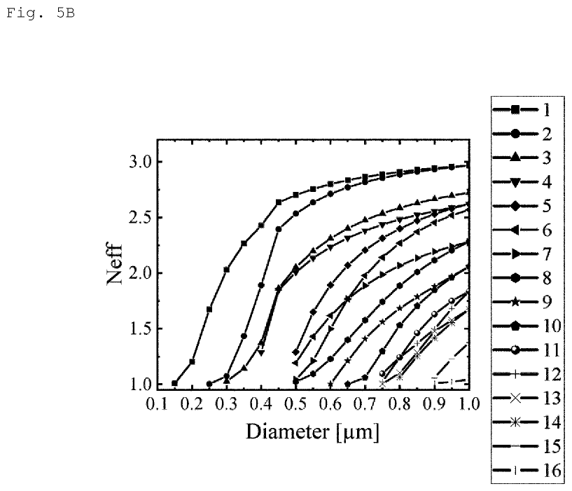

For example, in the case of materials in the telecommunication wavelength band, light propagates in a single mode in a nanowire with a diameter of the order of 400-500 nm, as shown in FIG. 5A. Note that, in FIG. 5A, numbers in the legend indicate mode orders. Here, in FIG. 5A, a 1st-order mode and a 2nd-order mode are shown overlapping, indicating that they are degenerate.

When processing with FIB as described above, the depth of about several hundred nm from the upper surface of the nanowire is damaged by ions implanted with FIB. For this reason, it is necessary to remove this portion. Therefore, in the process described with reference to FIG. 2A, the nanowires 121 having a diameter several hundred nm larger than the diameter of the target are prepared and disposed (transferred) on the substrate 101

The nanowires 102 formed by etching the thick nanowires 121 described above from above perpendicularly to the plane of the substrate 101 by a dry etching method having vertical anisotropy have a smaller diameter as a whole and the aspect ratio of the diameter changes. FIG. 5B shows the waveguide mode of the nanowire 102 obtained using the processing nanowire 121 with an initial diameter of 1 μm through the dry etching method described above. In FIG. 5B, the diameter on the horizontal axis is the minor axis. Also, in FIG. 5B, the numbers in the legend indicate the mode order.

In FIG. 5B, the mode of order 1 (fundamental mode) and the mode of order 2 are separated and this separation becomes clearer as the minor axis becomes smaller. In addition, it can be seen that the degeneracy between the 1st-order mode and the 2nd-order mode is resolved (the degeneracy of the fundamental mode is resolved). If the diameter is smaller than 0.4 μm, the waveguide becomes a single mode, and if the degeneracy is resolved, the TM mode can be eliminated and the TE mode can be selectively extracted.

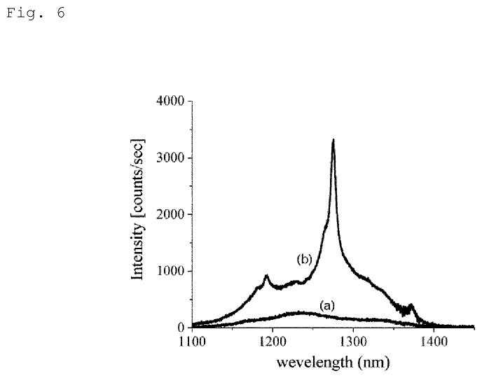

FIG. 6 shows the change in emission intensity of a nanowire laser in which a resonator using a one-dimensional photonic crystal is formed though processing using an FIB before and after the dry etching process to remove the damaged portion and make it elliptical. In FIG. 6, (a) shows the luminous intensity before the above dry etching treatment and (b) shows the luminous intensity after the above dry etching treatment. As shown in FIG. 6, the emission intensity is improved by removing the damaged portion.

### Embodiment 2

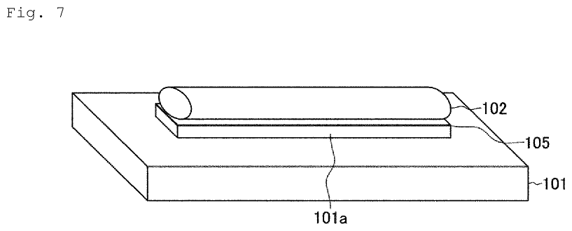

A nanowire laser according to Embodiment 2 of the present invention will be described below with reference to FIG. 7. This nanowire laser is composed of a nanowire 102 formed on a substrate 101 and a metal layer 105. The metal layer 105 is formed on the substrate 101 and in contact with the nanowire 102.

In this example, a convex portion 101a having a flat upper surface is formed on the substrate 101 and the metal layer 105 is formed on an upper surface of the convex portion 101a. Also, the nanowire 102 is disposed on and in contact with the metal layer 105. The upper surface of the convex portion 101a is formed parallel to the plane of the substrate 101. In addition, the convex portion 101a and the metal layer 105 have approximately the same area as the nanowire 102 when viewed from above. The nanowire 102 has an elliptical cross-sectional shape whose longitudinal direction is parallel to the plane of the convex portion 101a (substrate 101). Also, the nanowire 102 has a thickness in which the degeneracy of the fundamental mode is allowed to be resolved.

In Embodiment 2, the nanowire 102 and the metal layer 105 formed in contact with the nanowire 102 constitute a resonator. A plasmonic waveguide is formed in a place in which the metal layer 105 is in contact with the nanowire 102.

At the metal layer 105 in a place which is in contact with the nanowire 102, the light leaking out from the nanowire 102 induces surface plasmon polaritons on the surface of the metal layer 105. A surface plasmon polariton is a kind of elementary excitation in which surface plasmons induced on the surface of the metal layer 105 having free electrons are coupled with light radiated to the metal layer 105. The surface plasmon polariton induced in this way guides the plasmonic waveguide described above.

In Embodiment 2, a Fabry-Perot resonator is formed using end-face reflection of the nanowire 102 forming the above-described plasmonic waveguide. According to this configuration, since the plasmonic waveguide structure is used, a higher light confinement effect can be obtained due to the light confinement effect of plasmon compared to the end face reflection of a normal nanowire. In addition, in Embodiment 2, the cross-sectional shape of the nanowires 102 is elliptical so that a higher optical confinement effect can be obtained. As a result, according to Embodiment 2, the oscillation threshold value can be made lower.

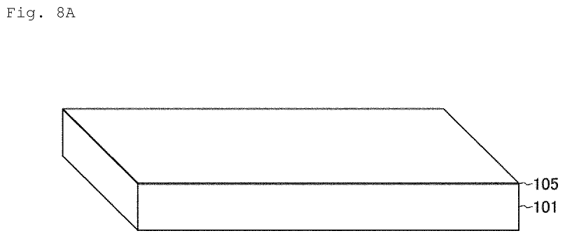

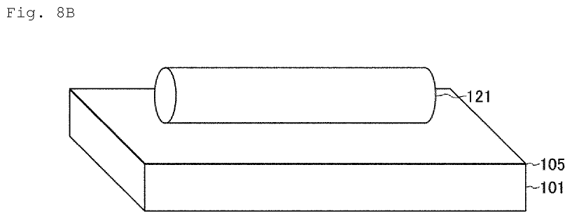

A method of producing a nanowire laser according to Embodiment 2 will be described below with reference to FIGS. 8A, 8B, and 8C.

First, a metal layer 105 is formed on a substrate 101, as shown in FIG. 8A. For example, the metal layer 105 made of Au can be formed on the substrate 101 by depositing gold (Au) using a well-known vapor deposition method. Subsequently, as shown in FIG. 8B, a nanowire 121 having a circular cross section and a predetermined diameter (for example, a diameter of 1 μm) is prepared and the prepared nanowire 121 is disposed (transferred) on the substrate 101 on which the metal layer 105 is formed (transfer) (disposition process).

Subsequently, the nanowire 121 is etched from above perpendicularly to the plane of the substrate 101 using a dry etching method having vertical anisotropy and an elliptical nanowire 102 having a cross-sectional shape whose longitudinal direction is parallel to the plane of the substrate 101 is formed (processing step). This processing changes the aspect ratio of the diameter of the nanowires 121 to form the nanowire 102 with an elliptical cross section. In this process, for example, a short length of the nanowire 102 can be 0.4 μm. In addition, through this processing, the metal layer 105 around the nanowire 102 and the substrate 101 are also etched to form the convex portion 101a and the nanowire 102 are disposed on the convex portion 101a via the metal layer 105 (refer to FIG. 7).

In the above-described Embodiment 2 as well, the nanowire 102 has an elliptical cross-sectional shape with different directions so that mode selectivity is improved and TE polarized waves can be selectively oscillated. Furthermore, it is possible to selectively oscillate the TE polarized wave in a single mode by making the nanowire 102 thick enough to eliminate the degeneracy of the fundamental mode.

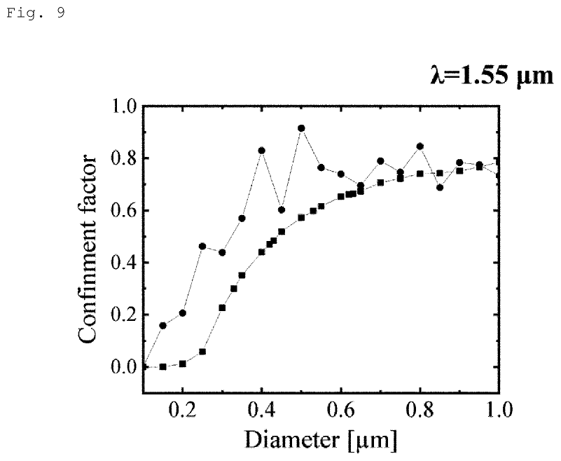

FIG. 9 shows optical confinement of the fundamental mode of a nanowire laser in which a nanowire with an elliptical cross-section obtained by processing a nanowire with a diameter of 1 μm using the above-mentioned producing method is disposed on a metal substrate and a nanowire laser in which a nanowire with a circular cross-section with a diameter of 1 μm is disposed on a metal substrate. The optical confinement in the fundamental mode of a nanowire laser with a nanowire with an elliptical cross section is indicated by the black circles in FIG. 9. The optical confinement in the fundamental mode of a nanowire laser using a nanowire with a circular cross section is indicated by the black circles in FIG. 9. As shown in FIG. 9, a nanowire laser in which a nanowire with an elliptical cross section is disposed on a metal substrate provides higher optical confinement.

As described above, according to embodiments of the present invention, since a nanowire having an elliptical cross-sectional shape is used, it is possible to provide a nanowire laser capable of selectively oscillating a TE polarized wave and efficiently coupling it to an optical waveguide.

Note that the present invention is not limited to the embodiments described above and many modifications and combinations can be implemented by those skilled in the art within the technical concept of the present invention.

### REFERENCE SIGNS LIST

101 Substrate
101a Convex portion
102 Nanowire
103a, 103b One-dimensional photonic crystal
104 Grating element

1-8. (canceled)

9. A nanowire laser, comprising:
a nanowire on a substrate and having an elliptical cross-sectional shape with a longitudinal direction parallel to a plane of the substrate; and
a resonator.

10. The nanowire laser according to claim 9, wherein the resonator comprises a one-dimensional photonic crystal on each end of the nanowire.

11. The nanowire laser of claim 10, wherein the one-dimensional photonic crystals comprise grating elements linearly and periodically provided at predetermined intervals.

12. The nanowire laser of claim 11, wherein the grating elements are columnar holes.

13. The nanowire laser according to claim 9, wherein the resonator comprises a metal layer on the substrate and in contact with the nanowire.

14. The nanowire laser according to claim 9, wherein the nanowire has a thickness in which degeneracy in a fundamental mode is resolvable.

15. The nanowire laser of claim 9, wherein the nanowire is disposed on a convex portion of the substrate.

16. The nanowire laser of claim 15, wherein the convex portion has a flat upper surface formed parallel to the plane of the substrate.

17. A method of forming a nanowire laser, comprising:
disposing a nanowire with a circular cross section on a substrate;
etching the nanowire from above perpendicular to a plane of the substrate using a dry etching method having perpendicular anisotropy, wherein after the etching, a cross section of the nanowire has an elliptical shape with a longitudinal direction parallel to the plane of the substrate; and
forming a resonator.

18. The method according to claim 17, wherein forming the resonator comprises forming a one-dimensional photonic crystal on each end of the nanowire.

19. The method according to claim 17, wherein forming the resonator comprises forming a metal layer on a surface of the substrate between the substrate and the nanowire.

20. The method according to claim 17, wherein etching the nanowire comprises forming the nanowire to have a thickness in which degeneracy of a fundamental mode is resolvable.

21. A method, comprising:
disposing a nanowire having a circular cross-section on a substrate;
forming an oxide film on a surface of the nanowire;
forming one-dimensional photonic crystals on each of a first end and a second end of the nanowire with a space therebetween; and
etching the nanowire from above perpendicularly to a plane of the substrate through a dry etching method having perpendicular anisotropy to form an elliptical nanowire having a cross-sectional shape whose longitudinal direction is parallel to the plane of the substrate, the one-dimensional photonic crystals forming a resonator.

22. The method of claim 21, wherein the one-dimensional photonic crystals comprise grating elements spaced periodically at predetermined intervals.

23. The method of claim 22, wherein the grating elements are columnar holes.

24. The method of claim 21, wherein the nanowire is disposed on a convex portion of the substrate.

25. The method of claim 24, wherein the convex portion has a flat upper surface formed parallel to the plane of the substrate.

26. The method of claim 21, wherein the nanowire has a thickness in which degeneracy of a fundamental mode is resolvable.

27. The method of claim 21, wherein the nanowire is configured to selectively oscillate a TE polarized wave after the etching step.
